(19) United States
(12) Patent Application Publication
(10) Pub. No.: US 2023/0013869 A1
(43) Pub. Date: Jan. 19, 2023

(54) BACK COVERS

(71) Applicant: Hewlett-Packard Development Company, L.P., Spring, TX (US)

(72) Inventors: Chi-Hsuan Hung, Taipei City (TW); Fu-Yi Chen, Taipei City (TW)

(73) Assignee: Hewlett-Packard Development Company, L.P., Spring, TX (US)

(21) Appl. No.: 17/786,609

(22) PCT Filed: Dec. 20, 2019
(86) PCT No.: PCT/US2019/067869

§ 371 Date: Jun. 17, 2022

(51) Int. Cl. H05K 5/02; H05K 7/20

(52) U.S. Cl. CPC H05K 5/0213; H05K 7/20145; H05K 7/20972

(57) ABSTRACT

Examples of back covers for devices are described. In an example, the back cover includes an air-vent, and a region of a surface of the back cover directing air dispensed by a cooling unit of the device toward the air-vent.

### BACKGROUND

Devices, such as display devices and All-in-One devices, include display panels and electronic units. In such a device, the display panel and the electronic units may be housed in a housing with a back cover. The electronic units may be disposed on the back cover. A cooling unit may be installed within the housing to absorb or expel the heat generated by the electronic units during their operation.

### BRIEF DESCRIPTION OF FIGURES

The detailed description is provided with reference to the accompanying figures, wherein:

FIG. 1A illustrates a schematic view of a back cover, according to an example;

FIG. 1B illustrates a top sectional view of the back cover of FIG. 1A;

FIG. 1C illustrates a top sectional view of the back cover of FIG. 1A;

FIG. 2 illustrates a schematic view of a back cover, according to an example;

FIG. 3 illustrates a schematic view of a device having a back cover, according to an example;

FIG. 4 illustrates a schematic view of a device having a back cover, according to an example;

FIG. 5 illustrates a schematic view of a device having a back cover, according to an example;

FIG. 6 illustrates a schematic view of a device having a back cover, according to an example; and

FIG. 7 illustrates a schematic view of a device having a back cover, according to an example.

### DETAILED DESCRIPTION

Electronic units installed within a housing of a display device, an All-in-One device, and such, may generate heat during their operation. The housing of such a device may include a back cover. An air-vent on a surface of the back cover is provided through which the heat generated by the electronic units may be expelled. The device may include a cooling unit, for example a fan unit, that absorbs the generated heat and dispenses hot air, after absorbing the generated heat, toward the air-vent. The air-vent may be provided on an edge of the back cover.

For a device which reduces in thickness towards the edges, the back cover may be curved. The thickness at the edges of the device may be smaller than the thickness of the cooling unit. The cooling unit may thus be disposed at some distance from the air-vent due to such dimensional constraints. The distance between the cooling unit and the air-vent causes the hot air, dispensed by the cooling unit, to circulate internally within the device, thereby increasing an internal temperature of the device. The device may fail to operate if the internal temperature exceeds a permissible internal temperature limit. In an example, the permissible internal temperature limit may be 49 degrees Celsius (° C.).

In some devices, a heat sink is disposed between the air-vent and a side of the cooling unit that dispenses the hot air for effective operation and for avoiding operational failure due to a high internal temperature of the device. The heat sink may be a copper foil or a thermal pad. The heat sink absorbs the heat from the dispensed hot air to prevent an increase in the internal temperature of the device. The heat sink in the electronic device is an additional component which increases the overall cost of the device.

The present subject matter describes example back covers for devices in which the thickness of the device reduces towards edges. The back covers of the present subject matter enable expelling heat, which is generated internally by electronic components of the device and absorbed by a cooling unit of the device, out of the device efficiently and in a cost-effective manner. Removal of heat from inside of the device prevents an increase in an internal temperature of the device, thereby avoiding operational failure of the device.

In an example, the back cover includes an air-vent and a plurality of channels. The plurality of channels is in a region of a surface of the back cover. Each channel includes a pair of walls that may be molded onto the surface of the back cover. Each channel of the plurality of channels directs air dispensed by the cooling unit of the device toward the air-vent.

When the device is in operation, the cooling unit absorbs heat generated by an electronic unit of the device and dispenses hot air. The plurality of channels directs the dispensed hot air toward the air-vent which further expels the hot air outside of the device. Expelling of the hot air out of the device via the air-vent prevents circulation of the hot air within the device and thus facilitates effective operation of the device without an operational failure due to a high internal temperature of the device. Further, the use of the plurality of channels for expelling the hot air, dispensed by the cooling unit, outside of the device makes the device cost-effective in comparison to the use of a heat sink inside the device for the same purpose.

Further, in an example, each of the pair of walls of each channel has a longitudinal edge. The longitudinal edge of a wall forms a free end of the wall. The longitudinal edges of the walls of the plurality of channels lie in a plane parallel to a plane in which edges of the back cover lie. Said example of the walls of the plurality of channels enables a display panel of the device to abut and rest on the longitudinal edges of the walls so as to avoid a gap between the longitudinal edges of the walls and the display panel in the assembled state of the device. The absence of a gap avoids circulation of hot air inside the device, which may adversely affect the working of the device.

The following detailed description refers to the accompanying drawings. Wherever possible, the same reference numbers are used in the drawings and the following description to refer to the same or similar parts. While several examples are described in the description, modifications, adaptations, and other implementations are possible. Accordingly, the following detailed description does not limit the disclosed examples. Instead, the proper scope of the disclosed examples may be defined by the appended claims.

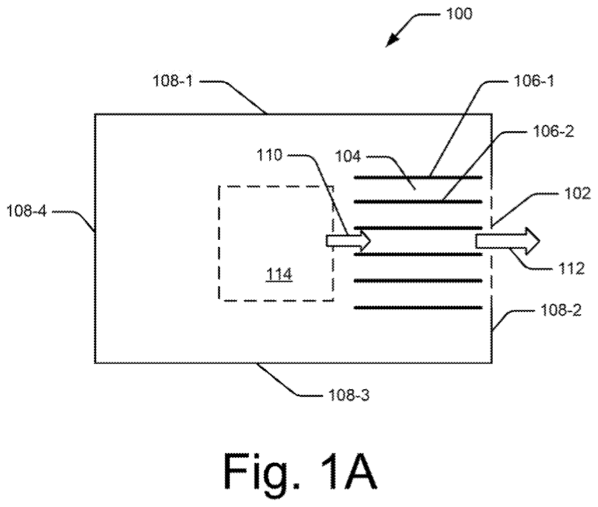

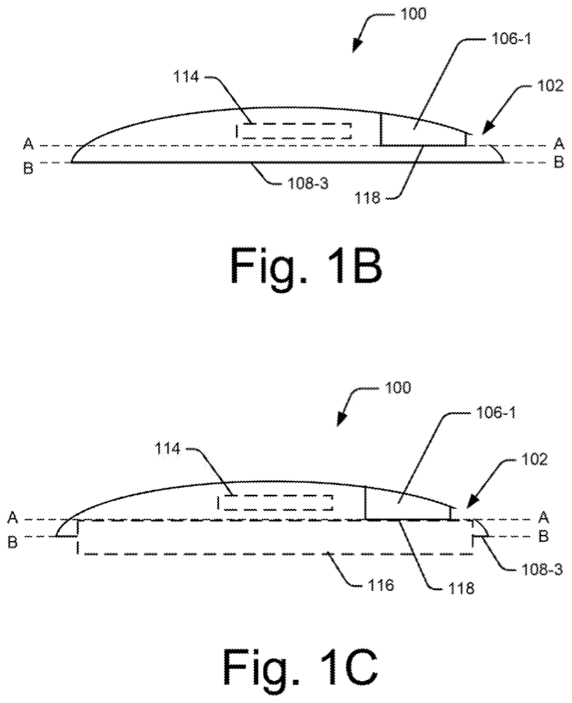

FIG. 1A illustrates a schematic view of a back cover 100, according to an example. The back cover 100 is used to cover a device (not shown in FIG. 1A) from a rear side of the device. The device may be a display device, for example, a display monitor or an All-In-One desktop computer. In one example, the back cover 100 may be curved. As shown, the back cover 100 includes an air-vent 102 on an edge of the back cover 100. The air-vent 102 provides a through-passage to air from the inside of the device to the outside of the device. Although, the air-vent 102 is shown on an edge 108-2 of the back cover 100, in an example, the air-vent can be at a different location on the back cover 100.

The back cover 100, as shown, includes a plurality of channels. The plurality of channels, individually and collectively referenced as 104, is disposed in a region of a surface of the back cover 100. In an example, the region of the surface in which the plurality of channels 104 is disposed may be a region between the air-vent 102 and a cooling unit 114 of the device. A channel 104 is a structure that provides a path for directing the flow of air from the cooling unit 114 towards the air-vent 102. Each channel 104 is formed by a pair of walls 106-1, 106-2 (collectively referred to as 106 hereinafter) that may be molded onto the surface of the back cover 100.

During operation of the device, the cooling unit 114 absorbs heat generated by an electronic unit (not shown in FIG. 1A) of the device and accordingly dispenses hot air. The electronic unit may, for example, be a motherboard, a processor, and such. The plurality of channels 104 of the back cover 100 directs the dispensed hot air toward the air-vent 102 which further expels the hot air outside of the device. Flow of the hot air dispensed by the cooling unit 114 toward the plurality of channels 104 is indicated by arrow 110 in FIG. 1A. Flow of the hot air directed by the plurality of channels 104 toward the air-vent 102 and further expelled outside of the device is indicated by arrow 112 in FIG. 1A. Expelling of the hot air outside of the device via the air-vent 102 prevents circulation of hot air within the device and thus facilitates effective operation of the device without an operational failure due to a high internal temperature of the device.

Further, each of the pair of walls 106 of each channel 104 has a free end in the form of a longitudinal edge. In an example, the longitudinal edges of the walls 106 of the plurality of channels 104 lie in a plane (not shown in FIG. 1A) parallel to a plane (not shown in FIG. 1A) in which edges 108-1, 108-2, 108-3, 108-4 (collectively referred to as 108 hereinafter) of the back cover 100 lie. The edges 108 collectively form the outer boundary of the back cover 100. FIG. 1B illustrates a top sectional view of the back cover 100 of FIG. 1A. The longitudinal edge of each wall 106 of each channel 104 is in plane A-A, and the edges 108 of the back cover 100 are in plane B-B, where plane A-A is parallel to plane B-B. It may be noted that one wall 106-1 and the longitudinal edge thereof, referenced as 118, and one edge 108-3 are visible in the top sectional view of the back cover 100 in FIG. 1B.

With the longitudinal edges of the walls 106 of the channels 104 in plane A-A parallel to plane B-B, a display panel (not shown in FIG. 1B), when assembled over the back cover 100, rests on and abuts the longitudinal edges of the walls 106. FIG. 10 illustrates a top sectional view of the back cover 100 of FIG. 1A, showing a display panel 116 abutting the longitudinal edge 118 of the wall 106-1. The abutment of the display panel 116 with the longitudinal edge 118 avoids formation of a gap between the walls 106 of the channels 104 and the display panel 116 in the assembled state of the device, which prevents circulation of hot air inside the device.

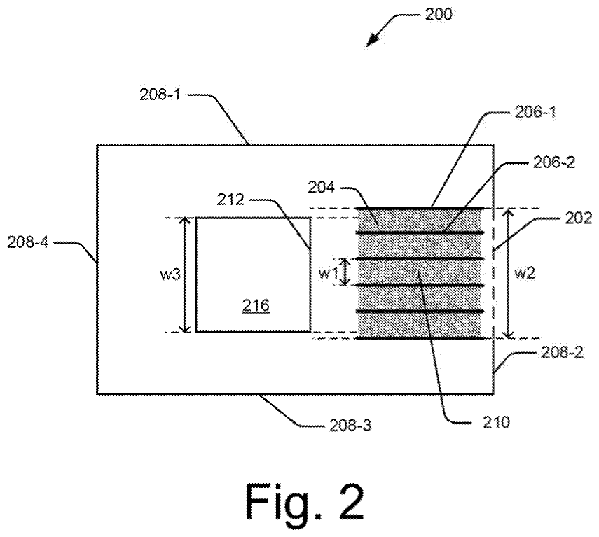

FIG. 2 illustrates a schematic view of a back cover 200, according to an example. The back cover 200 has four edges 208-1, 208-2, 208-3, 208-4 and is used to cover a device (not shown in FIG. 2) from a rear side of the device, as described with reference to FIG. 1A. As shown, the back cover 200 includes an air-vent 202 on the edge 208-2, similar to the air-vent 102 of the back cover 100 of FIG. 1A. The back cover 200 includes a plurality of channels similar to the plurality of channels 104 of the back cover 100. The plurality of channels of the back cover 200 are individually and collectively referenced as 204. Each channel 204 is a structure formed by a pair of walls 206-1, 206-2 (collectively referred to as 206 hereinafter) that may be molded onto the surface of the back cover 200. In an example, the back cover 200 and the walls 206 of each channel 204 are made of a same material. In an example, the back cover 200 and the walls 206 of each channel 204 are made of different materials.

Further, the back cover 200 includes a rough surface 210 in the region of the surface of the back cover 200 in which the plurality of channels 204 is disposed. A rough surface may be referred to as a surface having a texture. The roughness of a surface is determined based on deviations in a surface profile of the surface. The deviations in the surface profile may be measured using a surface profiler, and the roughness may be quantified as a root-mean square value of the measured deviations. In an example, the rough surface 210 may have a roughness in a range of 2 μm to 3 mm.

In an example, the rough surface 210 is obtained by a roughening technique. In an example, the rough surface 210 may be molded using a die with a surface profile complementary to the rough surface 210. The rough surface 210 together with the plurality of channels 204 enhances the rate at which the hot air, dispensed by a cooling unit 216 of the device, is directed toward the air-vent 202. The rough surface 210 creates air flow paths to efficiently guide the hot air from the cooling unit 216 toward the air-vent 202.

Further, in an example, each channel 204 of the plurality of channels 204 has a width w1. The width w1 of a channel 204 is a minimum distance between the walls 206 of the channel 204. In an example, the plurality of channels 204 are of equal widths. In an example, the plurality of channels 204 are of variable widths.

Further, the plurality of channels 204 spans a width w2 on the surface of the back cover 200. The width w2 is a sum of distances between each pair of adjacent walls 206 and the thickness of the intermediary walls. Further, the cooling unit 216 has a side 212 that dispenses the air. The side 212 of the cooling unit 216 spans a width w3 along a direction in which the width w2 of the plurality of channels 204 is spanning. In an example, the width w2 of the plurality of channels 204 spans more than the width w3 of the side 212 of the cooling unit 216 that dispenses the air. The width w2 is greater than the width w3 so that the channels 204 effectively receive the hot air dispensed from the side 212 of the cooling unit 216 to direct the received air toward the air-vent 202. In an example, the width of the plurality of channels 204 spans equally to the width of the side 212 of the cooling unit that dispenses the air. In an example, the width of the plurality of channels is equal to a width of a portion of the side of the cooling unit 216, where the portion dispenses the air from the cooling unit 216.

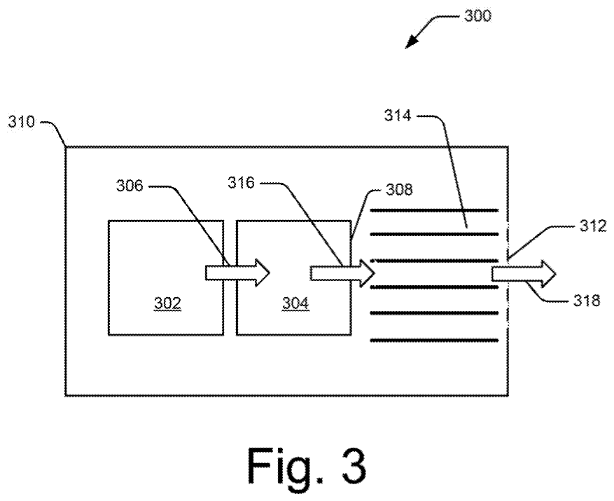

FIG. 3 illustrates a schematic view of a device 300 having a back cover 310, according to an example. The device 300 includes an electronic unit 302 and a cooling unit 304. The cooling unit has a side 308 that dispenses air. When the device 300 is in operation, air circulated by the cooling unit 304 absorbs heat generated by the electronic unit 302 and the side 308 of the cooling unit 304 dispenses hot air after absorbing the generated heat. The absorption of heat by the cooling unit 304 is indicated by arrow 306.

Further, the back cover 310 of the device 300 covers a rear side (not shown) of the device 300. The back cover 310 includes an air-vent 312 and a plurality of channels. The plurality of channels individually and collectively are referenced as 314 and may be similar to the plurality of channels 104 and 204 described with reference of FIG. 1A and FIG. 2. The air-vent 312 may be similar to the air-vent 102 of FIG. 1A. The plurality of channels 314 is disposed in a region of a surface of the back cover 310 between the air-vent 312 and the side 308 of the cooling unit 304. The surface of the back cover 310, on which the plurality of channels 314 is disposed, faces the electronic unit 302.

Each channel 314 of the plurality of channels 314 directs the hot air, dispensed by the side 308 of the cooling unit 304, toward the air-vent 312. The air-vent 312 further expels the directed hot air outside of the device 300. Flow of the hot air dispensed by the side 308 of the cooling unit 304 toward the plurality of channels 314 is indicated by arrow 316. Flow of the hot air directed by the plurality of channels 314 toward the air-vent 312 and further expelled outside of the device 300 is indicated by arrow 318. Expelling of the hot air out of the device 300 via the air-vent 312 prevents hot air circulation within the device 300 and thus facilitates effective operation of the device 300 without an operational failure due to a high internal temperature of the device 300. The hot air is expelled outside of the device 300 to keep the internal temperature of the device 300 below a permissible limit in which the device 300 can operate. In an example, the permissible limit of the internal temperature of the device 300 may be 49° C.

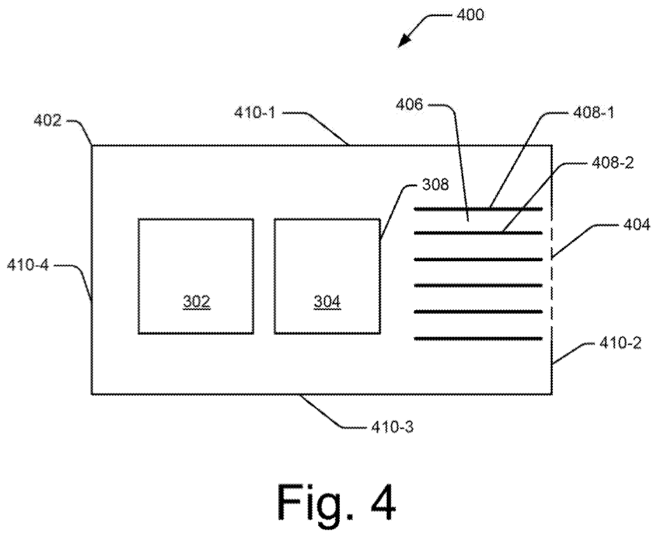

FIG. 4 illustrates a schematic view of a device 400 having a back cover 402, according to an example. The device 400 may be similar to the device 300 of FIG. 3 and includes the electronic unit 302 and the cooling unit 304. The back cover 402 of the device 400 includes an air-vent 404 and a plurality of channels, individually and collectively referenced as 406. The plurality of channels 406 may be similar to the plurality of channels 104 of FIG. 1A. The plurality of channels 406 is disposed in a region of a surface of the back cover 402 between the air-vent 404 and the side 308 of the cooling unit 304 that dispenses the hot air, during operation of device 400.

Each channel 406 of the plurality of channels 406 of the back cover 402 includes a pair of walls 408-1, 408-2 (collectively referred to as 408 hereinafter). The walls 408 of the pair are molded onto the surface of the back cover 402. Each of the pair of walls 406 of each channel 406 has a longitudinal edge. In an example, the longitudinal edges of the walls 406 of the plurality of channels 406 lie in a plane (not shown in FIG. 4) parallel to a plane (not shown in FIG. 4) in which edges 410-1, 410-2, 410-3, 410-4 (collectively referred to as 410 hereinafter) of the back cover 402 lie. The plane in which the longitudinal edges of the walls 406 lie is similar to plane A-A of FIG. 1B. The plane in which the edges 408 lie is similar to plane B-B of FIG. 1B. Similar to as described with reference to FIG. 2, the width of the plurality of channels 406 spans more than the width of the side 308 of the cooling unit 304 that dispenses the hot air.

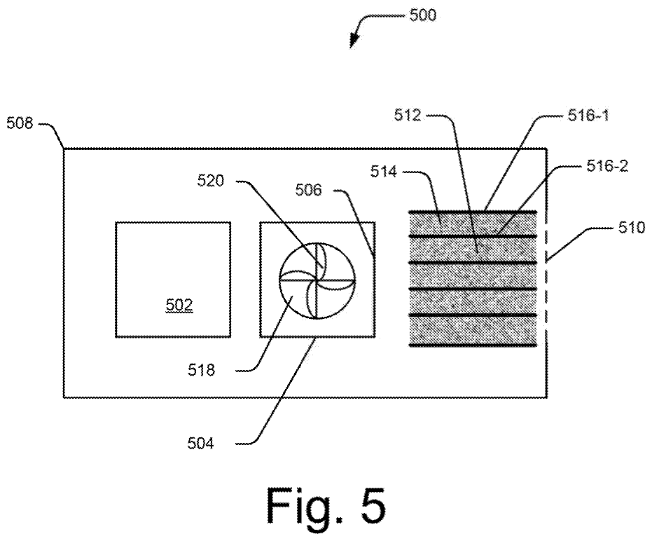

FIG. 5 illustrates a schematic view of a device 500 having a back cover 508, according to an example. The device 500 may be similar to the device 400 of FIG. 4. The device 500 includes an electronic unit 502 and a cooling unit 504, similar to the electronic unit 302 and the cooling unit 304, respectively. Further, the back cover 508 of the device 500 has an air-vent 510 and a plurality of channels (individually and collectively are referenced as 514), similar to the air-vent 404 and the plurality of channels 406, respectively.

Further, the back cover 508 includes a rough surface 512 in the region of the surface of the back cover 508, on which the plurality of channels 514 is disposed. The rough surface 512 may be similar to the rough surface 210 described with reference to FIG. 2. In an example, the rough surface 210 may have a roughness in a range of 2 μm to 3 mm.

Further, as shown in FIG. 5, the cooling unit 504 includes an inlet 518, a fan unit 520 and an outlet (not shown in FIG. 5) disposed on a side 506 of the cooling unit 504. The fan unit 520 operates to circulate air from the inlet 518 to the outlet on the side 506. The circulated air absorbs the heat generated by the electronic unit 502, when the device 500 is in operation. Further, the outlet on the side 506 of the cooling unit 504 dispenses hot air after absorbing the generated heat. The hot air dispensed by the outlet on the side 506 is directed via the plurality of channels 514 and the rough surface 512 toward the air-vent 510 and further expelled outside of the device 500 via the air-vent 510.

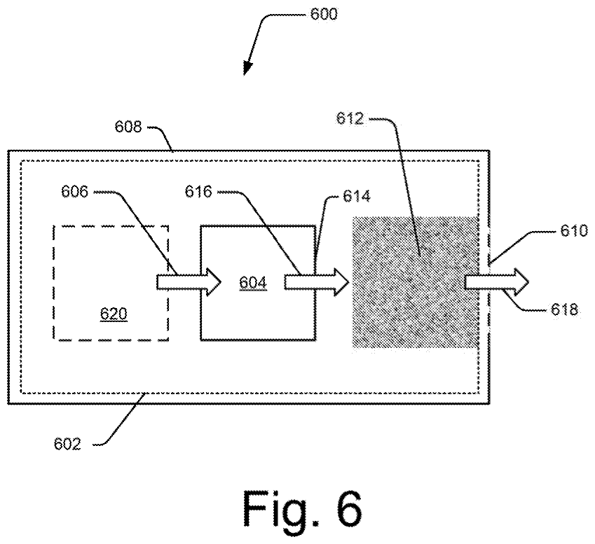

FIG. 6 illustrates a schematic view of a device 600 having a back cover 608, according to an example. As shown, the device 600 includes a display unit 602 and a cooling unit 604. The back cover 608 covers the device 600 from the backside. The cooling unit 604 may be similar to the cooling unit 504 as described with reference to FIG. 5. The display unit 602 is depicted by dotted lines so as to show components of the device 600 behind the display unit 602. The display unit 602 may include a display panel (not shown) and an electronic unit 620. In an example, the electronic unit 620 of the display unit 602 may, for example, be a processor that processes data to render content of the display panel. The display panel may be a light-emitting diode (LED)-based display, or such.

Further, the back cover 608 includes an air-vent 610 and a rough surface 612 in a region of a surface of the back cover 608. The region of the surface of the back cover 608 is between the air-vent 610 and a side 614 of the cooling unit 604 that dispenses the hot air, during operation of the device 600. The rough surface 612 may be similar to the rough surface 210 and the rough surface 512 described with reference to FIG. 2 and FIG. 5, respectively. In an example, the rough surface 612 has a roughness in a range of 2 μm to 3 mm.

The electronic unit 620 of the display unit 502 may generate heat when the device 600 is in operation. The cooling unit 604 absorbs the heat generated by the electronic unit 620 and accordingly dispenses hot air from the side 614. The direction of absorption of heat by the cooling unit 604 is indicated by arrow 606 and the direction in which the hot air is dispensed from the side 614 of the cooling unit 604 is indicated by arrow 616. The rough surface 612 receives the hot air, dispensed from the side 614 in the direction indicated by arrow 616, and is directed toward the air-vent 610 for further expelling out from the device 600 in a direction indicated by arrow 618.

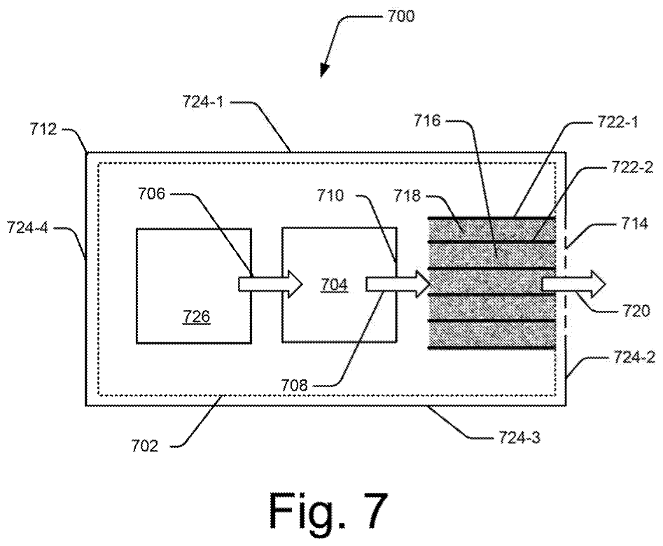

FIG. 7 illustrates a schematic view of a device 700 having a back cover 712, according to an example. The device 700 may be similar to the device 600 of FIG. 6. As shown, the device 700 includes a display unit 702 and a cooling unit 704. The back cover 712 covers the device 700 from the backside. The cooling unit 704 may be similar to the cooling unit 504 as described with reference to FIG. 5. The display unit 702 is depicted by dotted lines so as to show components of the device 700 behind the display unit 702. The display unit 702 includes a display panel (not shown) and an electronic unit 726. The display panel and the electronic unit 726 of the display unit 702 may be similar to display panel and the electronic unit 620 of the display unit 602.

The back cover 712 includes an air-vent 714 similar to the air-vents described earlier in the present disclosure. The back cover 712, as shown in FIG. 7, includes a rough surface 716 and a plurality of channels (individually and collectively referenced as 718) in a region of a surface of the back cover 712 between the cooling unit 704 and the air-vent 714. The rough surface 716 and plurality of channels 718 may be similar to the rough surface 210 and the plurality of channels 204 described with reference to FIG. 2. In an example, the rough surface 716 may have a roughness in a range of 2 μm to 3 mm.

The rough surface 716 and the plurality of channels 718 collectively direct the hot air dispensed from a side 710 of the cooling unit 704 toward the air-vent 714 so as to expel the hot air out of the device 700. The direction in which the cooling unit 704 absorbs heat generated by the electronic unit 726 is indicated by arrow 706. The flow of the hot air dispensed by the cooling unit 704 toward the rough surface 716 and plurality of channels 718 is indicated by arrow 708. The flow of the hot air directed by the rough surface 716 and plurality of channels 718 toward the air-vent 714 and further out of the device 700 is indicated by arrow 720.

In an example, each channel 718 includes a pair of walls 722-1, 722-2 (collectively referred to as 722 hereinafter) that may be molded onto the surface of the back cover 712. Each wall 722 of each channel 718 has a longitudinal edge. In an example, the longitudinal edges of the walls 722 of the plurality of channels 718 lie in a plane (not shown in FIG. 7) parallel to a plane (not shown in FIG. 7) in which edges 724-1, 724-2, 724-3, 724-4 (collectively referred to as 724 hereinafter) of the back cover 712 lie. The plane in which the longitudinal edges of the walls 722 lie may be similar to plane A-A of FIG. 1B. The plane in which the edges 724 lie may be similar to plane B-B of FIG. 1B. With such an arrangement of the walls 722 of the channels 718, the display panel of the display unit 702 abuts and rests on the longitudinal edges of the walls 722. As a result, substantially no gap is formed between the walls 722 and the display panel of the display unit 702. The absence of a gap between the walls 722 and the display panel of the display unit 702 avoids circulation of hot air inside the device 700.

Further, the back covers and the walls of the channels described in the present disclosure may be made of a plastic material. In an example, the plastic material may include, but is not limited to, Acrylonitrile Butadiene Styrene (ABS) or a combination of ABS and Polycarbonate (PC). In an example, the back cover and the walls of each channel described in the present disclosure are made of a same material. In an example, the back cover and the walls of each channel described in the present disclosure are made of different materials.

Although examples for the present disclosure have been described in language specific to structural features and/or methods, it is to be understood that the appended claims are not limited to the specific features or methods described herein. Rather, the specific features and methods are disclosed and explained as examples of the present disclosure.

We claim:

1. A back cover for a device, the back cover comprising:
an air-vent; and
a plurality of channels in a region of a surface of the back cover to direct air dispensed by a cooling unit of the device toward the air-vent, walls of each channel of the plurality of channels being molded onto the surface of the back cover, and a longitudinal edge of each of the walls of each channel of the plurality of channels being in a plane parallel to a plane in which edges of the back cover lie.

2. The back cover as claimed in claim 1, wherein the region of the surface of the back cover has a roughness in a range of 2 μm to 3 mm.

3. The back cover as claimed in claim 1, wherein the plurality of channels are of equal widths.

4. The back cover as claimed in claim 1, wherein the plurality of channels are of variable widths.

5. The back cover as claimed in claim 1, wherein the plurality of channels spans a width more than a width of a side of the cooling unit that dispenses the air.

6. The back cover as claimed in claim 1, wherein the back cover and the walls of each channel of the plurality of channels are made of a same material.

7. A device comprising:
an electronic unit;
a cooling unit to absorb heat generated by the electronic unit and dispense hot air; and
a back cover comprising:
an air-vent; and
a plurality of channels in a region of a surface of the back cover, facing the electronic unit, between the air-vent and a side of the cooling unit that dispenses the hot air to direct the hot air toward the air-vent.

8. The device as claimed in claim 7, wherein each channel of the plurality of channels comprises a pair of walls molded onto the surface of the back cover, and each of the pair of walls of each channel of the plurality of channels has a longitudinal edge in a plane parallel to a plane in which edges of the back cover lie.

9. The device as claimed in claim 7, wherein the region of the surface of the back cover has a roughness in a range of 2 μm to 3 mm.

10. The device as claimed in claim 7, wherein the plurality of channels spans a width more than a width of the side of the cooling unit that dispenses the hot air.

11. A device comprising:
a display unit;
a cooling unit to absorb heat generated by the display unit and dispense hot air; and
a back cover comprising:
an air-vent; and
a rough surface in a region of a surface of the back cover, facing the display unit, between the air-vent and a side of the cooling unit that dispenses the hot air to direct the hot air toward the air-vent, wherein the rough surface has a roughness in a range of 2 μm to 3 mm.

12. The device as claimed in claim 11, wherein the region of the surface of the back cover comprises a plurality of channels between the air-vent and the side of the cooling unit that dispenses the hot air to direct the hot air toward the air-vent.

13. The device as claimed in claim 12, wherein each channel of the plurality of channels comprises a pair of walls molded onto the surface of the back cover, and each of the pair of walls of each channel of the plurality of channels has a longitudinal edge in a plane parallel to a plane in which edges of the back cover lie.

14. The device as claimed in claim 13, wherein the back cover and the pair of walls of each channel of the plurality of channels are made of a same material.

15. The device as claimed in claim 13, wherein the back cover and the pair of walls of each channel of the plurality of channels are made of different materials.
